(19) United States
(12) Patent Application Publication
(10) Pub. No.: US 2017/0170359 A1
(43) Pub. Date: Jun. 15, 2017

(54) METHOD FOR PRODUCING A THIN-FILM STACK THAT CAN BE DISBONDED FROM ITS SUBSTRATE

(71) Applicant: NEXCIS, ROUSSET CEDEX (FR)

(72) Inventors: Brendan DUNNE, Gardanne (FR); Stéphanie ANGLE, Beaurecueil (FR)

(21) Appl. No.: 15/116,979

(22) PCT Filed: Dec. 29, 2014
(86) PCT No.: PCT/EP2014/079393

§ 371 Date: Aug. 5, 2016

(30) Foreign Application Priority Data
Feb. 5, 2014 (FR) 1450890

(51) Int. Cl. H01L 31/18

(52) U.S. Cl. CPC H01L 31/1864

(57) ABSTRACT

A method for producing a thin-film solar cell on an initial substrate, the thin-film solar cell being removable from the initial substrate, the thin-film solar cell including a rear metal layer and a thin-film stack including a p-n junction, the method including depositing the rear metal layer on the initial substrate by sputtering; forming the thin-film stack on the rear metal layer, wherein the power, temperature and pressure used to deposit the rear metal layer are chosen so as to introduce shear stress into the rear metal layer in a controlled manner.

### TECHNICAL FIELD

The present invention relates to a method for producing a thin-film stack that can be disbonded from its substrate.

### STATE OF THE PRIOR ART

The document “Peel and stick: fabricating thin film solar cell on universal substrates” of Chi Hwan, Dong Rip Kim, In Sun Cho, Nemeth William, Qi Wang & Xiaolin Zheng publihed on the 20 Dec. 2012 in the journal Nature describes a method for producing a thin-film solar cell (TFSC) that can be disbonded from its substrate. To do so, the method firstly proposes depositing a layer of nickel on a substrate made of SiO₂, then depositing the thin-film solar cell on the layer of nickel. An adhesive layer is then applied on the thin-film solar cell, then a protective layer is deposited on the adhesive layer. The whole assembly thereby formed is then immersed in water. A corner of the adhesive is then raised so as to enable the penetration of molecules of water at the interface between the substrate and the nickel layer. The presence of water at the interface between the layer of nickel and the substrate makes it possible to break the bonds between these two layers such that the layer of nickel, and thus the thin-film solar cell that covers it, can be disbonded from the substrate. This stack may then be re-bonded on the desired substrate. The method described in this document thus makes it possible to produce thin-film solar cells on all types of substrate and no longer only on glass substrates.

Nevertheless, this method requires the use of an insert layer made of nickel between the substrate and the thin-film solar cell, which complicates the method. Moreover, the method requires the immersion in water of the thin-film solar cell, which can deteriorate the thin-film solar cell. To remedy this, a protective layer is deposited on the adhesive to avoid infiltrations of water. Nevertheless, this protective layer has to be properly laid to avoid infiltrations of water and once more this complicates the method.

### DESCRIPTION OF THE INVENTION

The invention aims to overcome the drawbacks of the prior art by proposing a method for producing a thin-film solar cell that can be disbonded from its original substrate so as to be able to be deposited on all types of substrates, which is simpler than those of the prior art.

Another aim of the invention is to propose a method for producing a thin-film solar cell that can be disbonded from its original substrate so as to be able to be deposited on all types of substrates, which does not risk deteriorating the solar cell.

To do this, the invention proposes no longer depositing an insert layer between the thin-film solar cell and the substrate, but directly using a metal layer of the thin-film solar cell as weakening layer that can be disbonded easily from the substrate. To do so, the invention proposes introducing stresses into this metal layer in a deliberate and controlled manner by playing on the parameters of depositing this layer so that it adheres sufficiently to the substrate during the steps of depositing other layers of the thin-film solar cell, but that it can be easily disbonded from the substrate once these deposition steps have ended.

More precisely, a first aspect of the invention relates to a method for producing a thin-film solar cell on an initial substrate, the thin-film solar cell being able to be disbonded from the initial substrate, the thin-film solar cell comprising:
a rear metal layer intended to form a rear electrical contact,
a thin-film stack comprising a p-n junction, the method comprising the following steps :
depositing the rear metal layer on the initial substrate by sputtering;
forming the thin-film stack on the rear metal layer;
   the power, the temperature and the pressure used to deposit the rear metal layer being chosen so as to introduce shear stress into the rear metal layer in a controlled manner.

Thus, the method according to the invention proposes introducing stresses in the rear metal layer in a deliberate and controlled manner so as to be able to disbond it easily from the initial substrate at the end of the steps used to deposit layers of the thin-film solar cell. It then suffices to disbond, for example manually, a corner of the thin-film solar cell, to disbond completely the thin-film solar cell. There is thus no longer need to use water or an intermediate layer between the thin-film solar cell and the initial substrate to be able to disbond it: the rear metal layer, which will serve to form the rear metal contacts, also serves as weakening layer that ensures the bond between the solar cell and the initial substrate during the deposition steps and which can be disbonded from the initial substrate at the end of these steps thanks to the presence of shear stresses in the rear metal layer. Another advantage of the method according to the invention is that it can be implemented on a large variety of initial substrates contrary to the methods of the prior art, which could only be implemented on SiO₂ substrates.

The method according to the invention may also have one or more of the characteristics hereafter taken independently or according to all technically possible combinations thereof.

The shear stresses are preferably chosen empirically so that:
the rear metal layer adheres to the initial substrate during the steps of depositing the thin-film stack,
the rear metal layer can be disbonded from the initial substrate at the end of these steps.

The stresses introduced into the rear metal layer are thus chosen notably as a function of the deposition methods used to form the thin-film stack. The more aggressive these deposition methods, the less the stresses introduced in the rear metal layer have to be important, and vice-versa.

The method applies quite particularly in the case where the initial substrate is made of glass. Nevertheless, the method could also be implemented on a metal, for example stainless steel or aluminium, on a polymer, for example polyamide. Initial substrates covered with a surface diffusion barrier, for example made of SiOₓN_{y}, Al₂O₃ or metal can also be used. These barriers make it possible to prevent the bleeding of Na from glass, or iron from metal.

According to a preferential embodiment, the rear metal layer is made of molybdenum Mo. Nevertheless, the rear metal layer could also be made of one of the following materials: W, Ni, Au, Ti.

The rear metal layer is preferably deposited with the following parameters so as to create the desired shear stresses in said layer:
the power used to deposit the rear metal layer is preferably comprised between 0.5 W/cm² and 10 W/cm², and in a more preferential manner between 3 and 8 W/cm²;
the temperature used to deposit the rear metal layer is preferably comprised between 25° C. and 200° C., and in a more preferential manner between 50 and 80° C.;
the pressure used to deposit the rear metal layer is preferably comprised between 1 μBar to 15 μBar, and in a more preferential manner between 1 μBar and 5 μBar.

The rear metal layer preferably has a thickness substantially equal to 450 nm.

Advantageously, the method further comprises a step during which the rear metal layer is disbonded from the initial substrate. To do so, a corner of the rear metal layer is preferably lifted manually then the rear metal layer is disbonded progressively from the initial substrate.

Advantageously, the method further comprises a step during which the thin-film solar cell is re-bonded on another substrate. This other substrate may for example be a plastic, metal or textile film, or instead a hard plastic or metal substrate. The method thus makes it possible to produce thin-film solar cells that can be bonded on all types of substrate simply and without deteriorating the characteristics of the thin-film solar cell.

The step of depositing the thin-film stack preferably comprises the following sub-steps:
depositing a first p-doped semiconductor;
depositing an interface layer;
depositing a second n-doped semiconductor.

The first p-doped semiconductor is preferably a CIGS alloy.

The thin-film stack preferably further comprises:
a layer of ZnO intended to form a transparent front contact face;
a collection grid intended to improve the collections of carriers.

The step of depositing the first semiconductor preferably comprises the following sub-steps:
depositing copper, indium, gallium by electrodeposition,
annealing at 580° C.,
annealing at 600° C.,
placing the whole assembly in a bath.

Such a deposition step is thus very aggressive for the interface between the rear metal layer and the initial substrate such that the stresses introduced into the rear metal layer must not be too great.

### BRIEF DESCRIPTION OF THE FIGS.

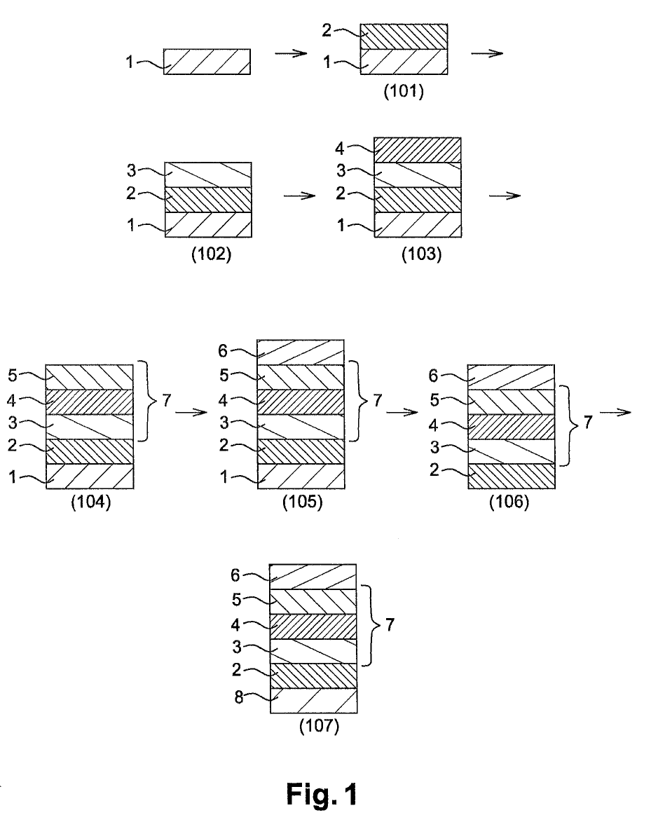

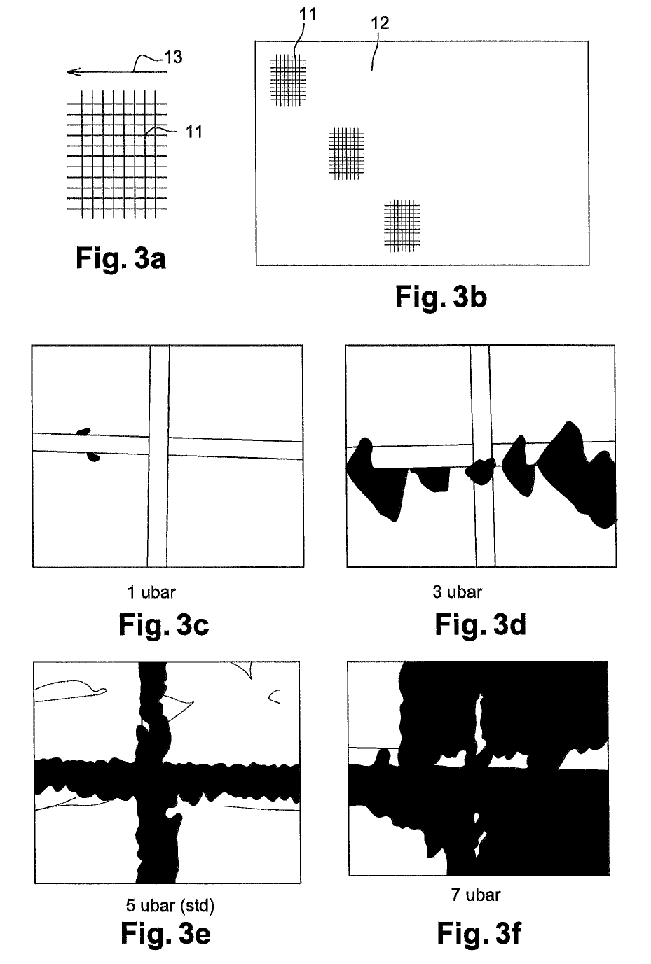

Other characteristics and advantages of the invention will become clear from reading the detailed description that follows, with reference to the appended figures, which illustrate:
FIG. 1, a schematic representation of the steps of a method according to an embodiment of the invention,
FIG. 2, a schematic representation in perspective of a solar cell obtained by a method according to an embodiment of the invention,
FIGS. 3a to 3f, schematic representations explaining the different steps and the results of an adhesion test carried out on a layer of molybdenum.

For greater clarity, identical or similar elements are marked by identical reference signs in all of the figures.

### DETAILED DESCRIPTION OF AT LEAST ONE EMBODIMENT

FIG. 1 represents the steps of a method for producing a solar cell on a substrate 1 according to an embodiment of the invention.

This method comprises a first step 101 of depositing a metal layer known as “rear metal layer” 2 on the substrate 1. The rear metal layer is preferably made of molybdenum. This rear metal layer 2 is deposited by sputtering. The parameters of depositing this rear metal layer will be detailed hereafter.

The method then comprises a step of forming a thin-film stack 7 comprising a p-n junction.

In this embodiment, this step of forming the thin-film stack 7 comprises a step 102 of depositing a first p-doped semiconductor 3 on the rear metal layer. This first p-doped semiconductor is preferably a CIGS alloy. To do so, the step 102 of depositing the first semiconductor preferably comprises firstly a step of depositing a layer of copper, then a layer of indium and finally a layer of gallium. These materials are preferably deposited by electrodeposition. The electrodeposition takes place in acid aqueous medium such that the bond between the rear metal layer and the initial substrate must withstand this acid aqueous medium. The step 102 then comprises a step of annealing at 580° C. under selenium atmosphere so as to cause a selenisation reaction, then a step of annealing at 600° C. under sulphur atmosphere so as to cause a sulphurisation reaction. The step 102 then comprises a step of passage in a bath containing KCN so as to remove all by-products produced during the selenisation and sulphurisation reactions. The steps of forming the first semiconductor 3 are thus very aggressive and the rear metal layer must remain fixed to the substrate during all of these steps.

In this embodiment, the step of forming the thin-film stack then comprises a step 103 of depositing a layer of cadmium sulphide CdS 4 on the first semiconductor 3, for example in a bath at 60° C.

In this embodiment, the step of forming the thin-film stack then comprises a step 104 of depositing transparent conductor oxide 5 which will make it possible to collect electrons from the p/n junction. This transparent conductor oxide 5 is preferably zinc oxide ZnO.

The method may also comprise a step 105 of forming front electrical contacts, as well as a step of discretisation of the future individual solar cells, and a step of forming electrical collectors.

The method according to this embodiment is particularly noteworthy in that during the step of depositing the rear metal layer by sputtering, the pressure, temperature and power used to deposit are chosen so as to create shear stresses in the rear metal layer 2. These shear stresses are going to make it possible to disbond easily the rear metal layer from the substrate. When the rear metal layer is made of molybdenum, in order to create sufficient shear stresses to disbond the rear metal layer:
the power used to deposit the rear metal layer is preferably comprised between 0.5 W/cm² and 10 W/cm², and in a more preferential manner between 3 and 8 W/cm²,
the temperature used to deposit the rear metal layer is preferably comprised between 25° C. and 200° C., and in a more preferential manner between 50 and 80° C.,
the pressure used to deposit the rear metal layer is preferably comprised between 1 μBar to 15 μBar, and in a more preferential manner between 1 and 5 μBar.

FIGS. 3a and 3b represent a disbondment test carried out on samples 12 obtained by a method according to the invention. Each sample 12 comprises:
an initial substrate;
a rear metal layer made of molybdenum of 500 nm.

The pressure used to deposit the rear metal layer has been modified so as to measure the adherence of the rear metal layer as a function of the pressure used to deposit this layer. The adhesion tests were carried out by applying a Scotch tape 11 at different locations of each sample 12 and by pulling it off sharply in the direction of the arrow 13. The results are represented in FIGS. 3c to 3f.

FIG. 3c represents the result of the test on a sample in which the rear metal layer has been deposited under a pressure of 1 μBar.

FIG. 3d represents the result of the test on a sample in which the rear metal layer has been deposited under a pressure of 3 μBar.

FIG. 3e represents the result of the test on a sample in which the rear metal layer has been deposited under a pressure of 5 μBar.

FIG. 3f represents the result of the test on a sample in which the rear metal layer has been deposited under a pressure of 7 μBar. As may be seen in these figures, the higher the deposition pressure, the more the rear metal layer disbonds easily, because the shear stresses in the rear metal layer increase with the pressure used to deposit this layer. Nevertheless, the pressure used to deposit the rear metal layer must not be too high, because the electrical resistance of the rear metal layer increases with the pressure used to deposit this layer. A compromise must thus be found so as to have a rear metal layer that disbonds easily but which has an electrical resistance that is not too high. The table below gives the values of the electrical resistance Rho of the rear metal layer of FIGS. 3c to 3f.

| | Deposition | Rho |
|---|---|---|
| | pressure (μBar) | (μOhms · cm) |
| Figure 3c | 1 | 13.1 |
| Figure 3d | 3 | 13.4 |
| Figure 3e | 5 | 16.3 |
| Figure 3f | 7 | 18.3 |

Thus, a pressure used to deposit the rear metal layer between 1 μBar to 15 μBar, and preferably between 1 and 5 μBar enables a good compromise between a rear metal layer that disbonds easily and an electrical resistance of the layer that is not too high.

The method according to the invention thus makes it possible to produce a thin-film solar cell that can be disbonded from its initial substrate. This solar cell can thus then be disbonded from its initial substrate then re- bonded on the chosen substrate.

The method may then comprise a step 106 during which the thin-film solar cell is disbonded from the initial substrate 1 by raising a corner of the thin cell and by pulling on it. The rear metal layer then disbonds from the initial substrate 1. The method may then comprise a step 107 during which the thin-film solar cell may be re-bonded on a new substrate 8. This new substrate 8 may for example be a plastic, metal or textile film.

Naturally, the invention is not limited to the embodiments described with reference to the figures and variants could be envisaged without going beyond the scope of the invention. The thin-film stack could notably have a composition different to that described with reference to the figures, such that the steps of depositing the thin-film stack could be different to those described with reference to the figures.

1. A method for producing a thin-film solar cell on an initial substrate, the thin-film solar cell being able to be disbonded from the initial substrate, the thin-film solar cell comprising
a rear metal layer configured to form a rear electrical contact,
a thin-film stack comprising a p-n junction, the method comprising:
depositing the rear metal layer on the initial substrate by sputtering, and
forming the thin-film stack on the rear metal layer; wherein a power, temperature and pressure used to deposit the rear metal layer are chosen so as to introduce shear stresses into the rear metal layer in a controlled manner.

2. The method for producing a thin-film solar cell on an initial substrate according to claim 1, wherein the rear metal layer is made of molybdenum.

3. The method for producing a thin-film solar cell on an initial substrate according to claim 1, wherein the power used to deposit the rear metal layer is comprised between 0.5 W/cm² and 10 W/cm².

4. The method for producing a thin-film solar cell on an initial substrate to claim 1, wherein the temperature used to deposit the rear metal layer is comprised between 25° C. and 200° C.

5. The method for producing a thin-film solar cell on an initial substrate according to claim 1, wherein the pressure used to deposit the rear metal layer is comprised between 1 μBar to 15 μBar.

6. The method for producing a thin-film solar cell on an initial substrate according to claim 5, wherein the initial substrate is made of glass.

7. The method for producing a thin-film solar cell on an initial substrate according to claim 1, further comprising a step during which the rear metal layer is disbonded from the initial substrate.

8. The method for producing a thin-film solar cell on an initial substrate according to claim 1, wherein the step of depositing the thin-film stack comprises the following sub-steps:
depositing a first p-doped semiconductor;
depositing an interface layer;
depositing a second n-doped semiconductor.

9. The method for producing a thin-film solar cell on an initial substrate according to claim 1, wherein the first p-doped semiconductor is a CIGS alloy.

10. The method for producing a thin-film solar cell on an initial substrate according to claim 1, wherein the step of depositing the first semiconductor comprises:
a step of depositing copper, indium, gallium by electrodeposition;
a first step of annealing at 580° C.;
a second step of annealing at 600° C.;
a step of placing the whole assembly in a bath.
